(19) United States
(12) Patent Application Publication
(10) Pub. No.: US 2026/0276687 A1
(43) Pub. Date: Sep. 17, 2026

(54) DEVICE FOR MEASURING THE ELECTRICAL RESISTANCE OF AN ELEMENT

(71) Applicant: ATEQ, Les Clayes-sous-Bois (FR)

(72) Inventor: Sylvain Ballet, Les Clayes-sous-Bois (FR)

(21) Appl. No.: 19/469,574

(22) PCT Filed: Mar. 27, 2024
(86) PCT No.: PCT/EP2024/058377

§ 371 Date: Sep. 26, 2025

(30) Foreign Application Priority Data
Apr. 14, 2023 (FR) FR2303728

(51) Int. Cl. G01R 27/14; G01R 1/20; G01R 1/28; G01R 1/30; G01R 31/00

(52) U.S. Cl. CPC G01R 27/14; G01R 1/203; G01R 1/28; G01R 1/30; G01R 31/008

(57) ABSTRACT

The present invention relates to a device (1) for measuring the resistance of an element (2), in particular an aircraft structural element, characterised in that the device (1) comprises:—a digital control circuit (5) configured, on the one hand, to control the value of a measurement current (IR) to be injected into the element to be tested (2) and, on the other hand, to determine, from the voltage value (VR) generated by the measurement current (IR), the resistance value of the element (2) being tested;—a digital-to-analogue conversion stage (8) configured to convert a digital signal into an analogue signal and vice versa;—an analogue measurement circuit (7) connected to the digital control circuit (5) via the converters and configured to: —generate a measurement current (IR) from a digital setpoint (Cm) originating from the digital control circuit (5); ·measure an analogue value of the voltage (VR) generated by the measurement current (IR); characterised in that the device (1) comprises a reference voltage source (3) connected to the conversion stage (8), the conversion stage (8) being configured to use the voltage value (Vref) generated by the reference source (3) for the conversion:—of digital signals (Cm), such as the digital setpoint (Cm) that controls the generation of a measurement current (IR) by the analogue measurement circuit (7), originating from the digital control circuit (5), into analogue signals (VC) intended for the analogue measurement circuit (7); and—of analogue signals (VR»), such as the voltage value (VR) measured across the terminals of the element (2) being tested, originating from the measurement circuit (7), into digital signals (LUext) intended for the digital control circuit (5).

The present invention relates to the field of devices for measuring the electrical resistance of an element, in particular for measuring small resistance values with accuracy, notably for measuring milliohm resistance values with less than 1% accuracy.

For example, when assembling an aircraft, such as a plane, an helicopter, a drone, etc. or later during maintenance operations, operators must check whether the parts are well assembled (or fixed) with each other. In particular, these checks can be made by measuring the resistance values between elements (or parts of an element).

Indeed, the resistance value is a physical value that measures the quality of the bound between elements: the lower this value, the better the bound. The bounds between the elements of an aircraft feature advantageously a low resistance value to reduce the damages when the aircraft is struck by lightning.

It shall be noted that this type of measurement makes also possible to check the metallization of parts, the quality of a soldering, etc.

As a rule, the measurement of a resistance value relies on applying a voltage or a current with a preset value to the element, whose resistance is measured, then, later, on measuring respectively the resulting current or voltage value, the link between voltage and current being, according to Ohm's law, the resistance value of the test element.

This results in the fact, on one hand, that the value of the voltage or current set/injected to the element must be known with as much accuracy as possible and, on the other hand, that the resulting value of the current or voltage must also be measured with as much accuracy as possible, of course to measure the resistance value with as much accuracy as possible relatively to the test element.

However, to apply an electrical value (tension or current) to elements, a dedicated device is used, which must comprise an electrical power source. This power source can provide voltage or current values with variations, in particular as a function of wear, temperature, and other environmental or intrinsic parameters. Ultimately, the variations out of control may alter the accuracy of the measurement of electrical resistance values.

In addition, this type of device features an electronic design that generally comprises digital or analogic circuits, wherein the digital circuit is a monitoring circuit, while the analogic circuit is a measurement circuit. Thus, this design requires digital-analogic converters, so that the circuits can communicate with each other, but these converters (and the conversions of electrical signals as a rule) induce additional errors on the measured and/or set/injected electrical values to an element.

Thus, the present invention suggests to partly remedy at least one of these drawbacks above with a new type of measurement device for measuring the resistance of an element, in particular of a structural element of an aircraft, characterized in that said device comprises:
a digital monitoring circuit configured to, on one hand, monitor the value of the measurement current to inject into the test element and, on the other hand, calculate from the voltage value generated by the measurement current the value of the resistance of the test element;
a digital-analogic conversion stage configured to convert a digital signal into an analogic signal and vice versa;
an analogic measurement circuit connected to said digital monitoring circuit through said digital-analogic conversion stage (i.e. through converters) and configured to:
   generate a measurement current out of a digital setpoint from the digital monitoring circuit;
   measure an analogic value of the voltage generated by the measurement current; characterized in that the device comprises a reference voltage source connected to said conversion stage, wherein said conversion stage is configured to use the voltage value generated by said reference source for the conversion:
of digital signals, such as the digital setpoint that monitors the generation of a measurement current by the analogic measurement circuit, from the digital monitoring circuit into analogic signals for the analogic measurement circuit, and
of analogic signals, such as the voltage value at the terminals of the test element, from the analogic monitoring circuit into digital signals for the digital monitoring circuit.

It shall be noted that “analogic signal” refers to physical values (voltage, current, etc.) with continuous variation, while “digital signal” refers to a signal with a finite number of states (or values), hence that it quantified.

Furthermore, it shall be noted that “electrical resistance” refers to a physical value that shows the ability of a material or, at least, of an element to allow the electric current to flow; this electrical resistance is usually measured in Ohms. However, the invention also refers to the case of an indirect measurement of an electrical resistance, as a measurement of the electrical conductivity (that is the inverse of the electrical resistance) of at least one element, a physical value that is usually measured in Siemens.

Having an unique and identical reference voltage source for the conversion of the various signals from the digital monitoring circuit and the analogic measurement circuit makes it possible to reduce the risks of error associated with these conversion, hence to improve the accuracy of the measurement of the electrical resistance value of the test element.

It shall also be noted that:
an analogic-digital converter is an electronic device or component, whose function is to turn an analogic value into a digital value encoded in several bytes, the converted signal being generally an electric voltage;
a digital-analogic converter is an electronic device or component, whose function is to turn a digital value (encoded on several bytes) into an analogic value, for example a voltage, which is proportional to the encoded digital value.

According to a possible characteristic, said conversion stage comprises two distinct signal converters:
a first digital-analogic converter;
a second analogic-digital converter;

In this example, said reference voltage source is connected to each of said converters. The reference voltage source is advantageously directly connected to each of said converters to limit the variations of tension generated by said source, in particular at the inputs of the converters.

According to another possible characteristic, the analogic circuit comprises a current generating assembly configured to convert a voltage value out of the digital-analogic converter into a measurement current.

According to another possible characteristic, the current generating assembly comprises at least a reference resistor, and preferably several reference resistors.

Advantageously, having several reference resistors makes notably possible to have several “current gauges” to test elements featuring resistances with very different orders of magnitude, which makes it possible to maintain good accuracy for different orders of magnitude of resistance.

According to another possible characteristic, said device comprises an amplification stage of the voltage as measured at the terminals of the test element (voltage generated by the measurement current).

According to another possible characteristic, said amplification stage is an instrumentation amplifier assembly.

It shall be noted that an instrumentation amplifier assembly is an electronic component (or circuit) designed to treat weak signals, in particular those from measurement sensors. Furthermore, the instrumentation amplifier assembly makes it possible to largely get rid of errors in connection with the common mode.

According to another possible characteristic, the amplification stage comprises a plurality of operational amplifiers and a plurality of resistors.

According to another possible characteristic, said device comprises a filtration stage configured to filter the analogic signal for conversion by the analogic-digital converter.

According to another possible characteristic, the digital monitoring circuit is configured to send a current setpoint as a digital setpoint. Indeed, said digital setpoint encodes a voltage value V_{c} at the output of the analogic-digital converter, which is converted into a measurement current I_{R}.

According to another possible characteristic, the voltage setpoint V_{c} of the current out of the digital-analogic converter is a function of the reference voltage V_{ref}, of the number of bits n₁ of the converter, of the values of the bits aₙ, and of a coefficient k.

The coefficient k is a constant, and the voltage out of the digital-analogic converter is defined by the following formula:

$${V}_{out} = k \cdot {V}_{ref} \cdot {\sum }_{i = 1}^{n} ( {2}^{n - i} \cdot {a}_{n - i} )$$

with:
   V_{ref}=maximum of the conversion
   k=proportionality ratio
   n=number of bytes of the converter
   aₙ=value of the byte n (1 or 0)

According to another possible characteristic, the voltage setpoint is sent to the input of the current generating assembly to generate a measurement current IR.

According to another possible characteristic, the voltage at the input of the analogic-digital converter generates a digital signal L_{Uext} at the output, which is a function of the reference voltage V_{ref}, of the number of bytes n₂ of the converter.

According to another possible characteristic, said device comprises a human-machine interface.

It shall be noted that human-machine interface refers to all the elements that make it possible to the user to interact with the device of the invention, in particular to monitor the device of the invention and exchange information with said device. For example, the human-machine interface comprises at least a display means, such as a touch screen or non-touch screen, buttons, a keyboard, etc.

According to another possible characteristic, said device comprises a Kelvin-type electrical connection, also called “four-wire connection”.

A Kelvin connection is a means that makes it possible to establish an electrical connection with a component, while considerably removing or reducing the effect of parasite resistances in relationship with the connection itself, such as the contact resistance and/or the resistance of the conductors. This is particularly critical in the context of the measurement of electrical values that require as accurate measurements as possible, for example for small resistance values, in particular less than 1 Ohm.

According to another possible characteristic, the digital monitoring circuit and the analogic measurement circuit are located on two distinct circuit boards.

In particular, having two distinct boards makes it possible to reduce the noise on the measurement circuit.

According to another possible characteristic, said device comprises an alert means, for example configured to warn the operator (or the user) about the injection of a measurement current IR, the end of the measurement and/or the determining (and display with the human-machine interface) of the electrical resistance value of a test element, that said measure is right, etc. Said alert means is, for example, an audio and/or light signal.

The invention will be better understood, and some other purposes, details, characteristics and advantages will show up more clearly in the following description of a particular embodiment of the invention, set forth as an illustration only and not limitatively, with reference to the appended pictures, where:

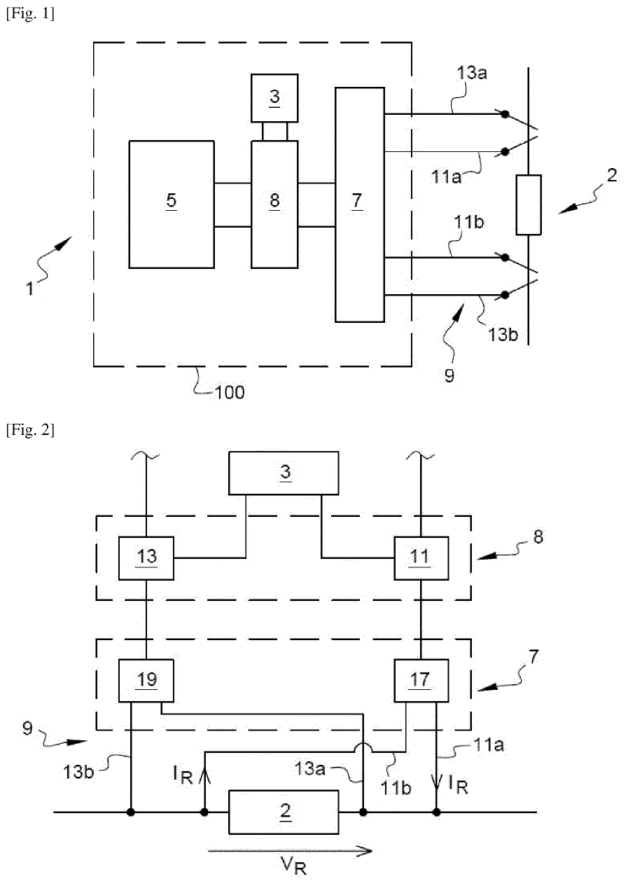

FIG. 1, referenced as FIG. 1, shows a very schematic view of a device for measuring a resistance according to the invention;

FIG. 2, referenced as FIG. 2, shows a very schematic and enlarged view of the part of the device dedicated to the measurement of FIG. 1;

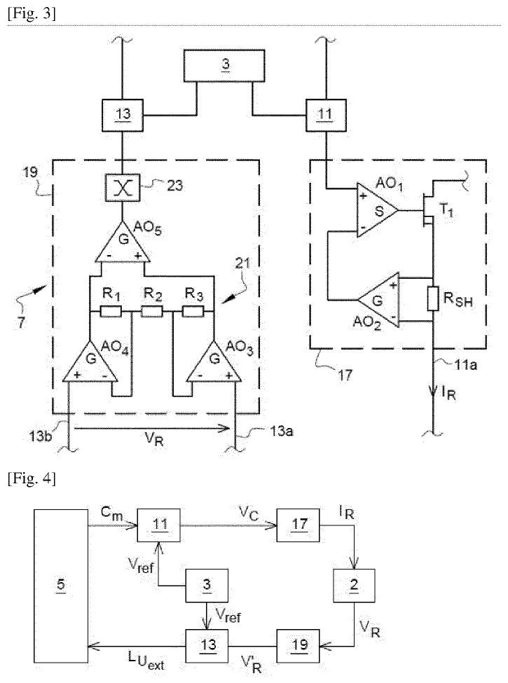

FIG. 3, referenced as FIG. 3, shows a very schematic and detailed view of the part of the device of FIG. 2;

FIG. 4, referenced as FIG. 4, is a block diagram that shows the conversion of the electrical signals from the device of FIG. 1.

FIG. 1 is a very schematic view of a device 1 of the invention, designed to measure the electrical resistance value of at least one element 2, such as structural elements of an airplane.

It shall be noted that electrical resistance refers to the value of electrical resistivity of an element, which means the tendency of an element to oppose the flow of an electrical current. The device 1 according to the invention can directly measure the electrical resistance of the element 2 or make an indirect measurement, which means by measuring a physical property that is proportional or inversely proportional to the electrical resistance, such as electrical conductivity, to eventually measure a value of electrical resistance.

Thus, said device 1 comprises a carter 100, for example made of plastic, that houses:
a power source 3 that is, for example, a reference power source;
an electronic monitoring circuit 5 and an electronic measurement circuit 7, which are advantageously featured as two distinct circuit boards;
a digital-analogic conversion stage 8 that links the monitoring circuit 5 to the measurement circuit 7 and that is configured to convert a digital signal into an analogic signal and vice versa;
an electrical connection 9 designed to connect the device 1, in particular the measurement circuit 7, to the element 2, whose electrical resistance value is measured.

The electrical connection 9 is advantageously a Kelvin or 4-wire connection. Thus, said Kelvin connection 9 comprises four electrical conductors 11a, 11b, 13a, 13b that usually end with clamps or spikes that are designed to connect or be applied to the at least one element 2, whose electrical resistance value is measured. In particular, the Kelvin connection 9 comprises two power conductors 11a, 11b and two measurement conductors 13a, 13b.

Thus, the power conductors 11a and 11b, more clearly visible at FIG. 2, are configured to inject an electrical current IR, called “measurement current”, into the test element 2, while the measurement conductors 13a and 13b are configured for the measurement of a voltage at the terminals of the element 2.

In this example, the Kelvin connection 9 makes it possible to measure the voltage VR generated by the measurement current IR by limiting, possibly by cancelling the effects of resistances resulting from the contacts and/or the conductors of said connection 9.

Furthermore, said device 1 advantageously comprises a human-machine interface (not pictured). The human-machine interface refers to all the elements that make it possible to the user to interact with the device 1 of the invention, in particular to monitor the device 1 and/or to exchange information with said device 1. Thus, the human-machine interface comprises, for example, at least a display means, such as a touch screen or non-touch screen, buttons, a keyboard, etc.

More specifically, said device 1 comprises two electronic circuits 5 and 7 that are:
a monitoring circuit 5 that is, on one hand, a digital circuit and, on the other hand, configured to monitor the value of a measurement current IR to inject into the element 2;
a measurement circuit 7 that is an analogic circuit, connected to said digital monitoring circuit 5 and configured, on one hand, to generate a measurement current IR according to a digital setpoint from said digital monitoring circuit 5 and, on the other hand, to measure an analogic value of the voltage VR generated by the measurement current IR,

It shall further be noted that the digital monitoring circuit 5 is connected to the human-machine interface and also has the function of managing/monitoring said interface.

It shall further be noted that the digital monitoring circuit 5 is an electronic entity that features, for example, one or several components such as microcontrollers, and that is notably configured to send and receive signals, treat data, store data, etc.

As for it, the conversion stage 8 is configured to use the voltage value generated by said power source 3 for the conversion:
of digital signals (in particular of the digital setpoint that will monitor the generation, in other words that will induce the creation or make generate, a measurement current IR by the measurement circuit 7) from the digital monitoring circuit 5 into analogic signals for the analogic measurement circuit 7, and
of analogic signals (in particular of a voltage value VR at the terminals of the test element 2) from the analogic monitoring circuit 7 into digital signals for the digital monitoring circuit 5.

Thus, during the test of an element 2, the digital monitoring circuit 5 sends a digital setpoint Cm (that is a digital signal) that is converted into an analogic signal by the conversion stage 8 for transformation by the analogic measurement circuit 7 into a measurement current IR that is injected by the electrical connection 9 into the element 2 (in particular through the power conductors 11a and 11b).

The flow of a measurement current I_{R} through the element 2 induces the creation of a voltage V_{R} at the terminals of said element 2. The voltage value V_{R} is measured thanks to the electrical connection 9, in particular thanks to measurement conductors 13a and 13b.

The voltage value V_{R} is an analogic signal that is treated (for example filtered and/or amplified) by the analogic measurement circuit 7 to be converted into a digital signal by the conversion stage 8 for the digital monitoring circuit 5.

As a result, the digital monitoring circuit 5 is configured to monitor a measurement current value I_{R} to inject into the element 2 and get a voltage value V_{R} (as a digital value) to measure the electrical resistance value of said element 2 from said values I_{R} and V_{R} as digital values. The conversion stage 8 converts the digital and analogic signals through said circuits 5 and 7.

Thus, the digital monitoring circuit 5 is configured to send a current setpoint as a digital signal coded as a voltage, which is then converted into an electrical current value. The voltage setpoint V_{c} of the current out of the digital-analogic converter 8 is a function of the reference voltage V_{ref}, of the number of bits n₁ of the converter, of the values of the bits an, and of a coefficient k that is a constant. This voltage V_{c} at the output can be written this way:

$${V}_{out} = k \cdot {V}_{ref} \cdot {\sum }_{i = 1}^{n} ( {2}^{n - i} \cdot {a}_{n - i} )$$

with:
   V_{ref}=maximum of the conversion
   k=proportionality ratio
   n=number of bytes of the converter
   aₙ=value of the byte n (1 or 0)

FIG. 2 is a schematic view and detail view of a part of the device 1 in FIG. 1, in particular of the power source 3 that works as a reference voltage source, of the conversion stage 8 and of the analogic measurement circuit 7.

The conversion stage 8 comprises a digital-analogic converter 11 and analogic-digital converter 13, each of them connecting the digital monitoring circuit 5 to the analogic measurement circuit 7. The transmission of analogic and digital signals between said circuits 5 and 7 is made respectively through said converters 11 and 13.

It shall be noted that an analogic-digital converter is an electronic device or component, whose function is to turn an analogic value into a digital value encoded in several bytes (the converted signal being generally an electric voltage).

It shall also be noted that a digital-analogic converter is an electronic device or component, whose function is to turn a digital value (encoded on several bytes) into an analogic value, for example a voltage, which is proportional to the encoded digital value.

Said reference voltage source 3 is connected (preferably directly) to each of said converters 11 and 13 to work as only reference for the conversion of digital signals into analogic signals and vice versa during exchanges of signals between said circuits 5 and 7.

The analogic measurement circuit 7 further comprises:
a current generating assembly 17 configured to generate a measurement current I_{R} designed to flow through the test element 2;
an analogic signal amplification stage 19, such as the voltage as measured at the terminals of the element 2 (voltage generated by the measurement current I_{R}).

Furthermore, the digital-analogic converter 11 connects the digital monitoring circuit 5 to the current generating assembly 17 of the analogic measurement circuit 7, while the analogic-digital converter 13 connects the amplification stage 19 to the digital monitoring circuit 5.

In particular, the digital monitoring circuit 5 is configured to send a digital setpoint Cₘ, thus a digital signal that codes a voltage value, which is to be converted into an analogic signal that corresponds to an output voltage value V_{c} of the digital-analogic converter 11, the assembly 17 being configured to convert (or transform) this output voltage value V_{c} of the converter 11 into a measurement current I_{R}.

FIG. 3 is a schematic and more detailed view of the measurement circuit 7 of FIG. 2.

As more specifically pictured there, the current generating assembly 17 comprises at least a reference resistor R_{SH}, a first and a second operational amplifier, respectively AO₁ and AO₂, and a transistor T₁.

The set made of said operational amplifiers, respectively AO₁ and AO₂, of the transistor T₁, and of the resistor R_{SH} constitute a voltage-current converter assembly.

In particular, the output of the first converter 11 (digital-analogic converter) is connected to the non-inverting input of the first operational amplifier AO₁ while the output of the first operational amplifier AO₁ is connected to the transistor T₁.

For example, the transistor T₁ is a MOSFET-type transistor, whose gate is directly connected to the output of the operational amplifier AO₁, while its emitter is directly connected to the non-inverting input of the second operational amplifier AO₂ and to one of the terminals of the resistor RSH. The other terminal of the resistor R_{SH} is connected to the inverting input of the second operational amplifier AO₂ and to the power conductor 11a of the electrical connection 9. Thus, the inverting and non-inverting inputs of the second operational amplifier AO₂ are connected to the terminals of the resistor RSH. Thus, the transistor T₁ regulates the value of the measurement current I_{R} as a function of the voltage value V_{c}, of the gain of the second operational amplifier AO₂ and of the value of the resistance RSH.

In addition, the output of the second converter AO₂ is connected to the input of the first operational amplifier AO₁. This way, the voltage V_{c} at the output of the first converter 11 is compared with the voltage at the terminals of the resistor RSH, to which a second operational amplifier AO₂ applies a gain.

In particular, said amplification stage 19 comprises an instrumentation amplifier assembly 21 and a filtration stage 23 that is configured to filter an analogic signal (notably noises) for conversion by the analogic-digital converter 13, such as the value of the voltage V_{R} at the terminals of the element 2.

Thus, the instrumentation amplifier assembly comprises a plurality of operational amplifiers AO₃, AO₄ and AO₅, and a plurality of resistors R₁, R₂ et R₃, respectively a first R₁, a second R₂ and a third R₃ resistor.

In particular, the measurement conductors 13a and 13b are respectively connected to the non-inverting inputs of the third and fourth operational amplifiers AO₃ and AO₄. Thus, a difference of the V_{R} voltages at the terminals of the test element 2 is applied at the non-inverting inputs of said operational amplifiers AO₃ and AO₄.

The first, second and third resistors R₁, R₂ and R₃ are serially connected. The terminals of this plurality of resistors are connected to the respective outputs of said third and fourth operational amplifiers AO₃ and AO₄.

Thus, one of the terminals of the first resistor R₁ is connected to the output of the third amplifier AO₃, while the other terminal is connected both to the second resistor R₂ and to the inverting input of the third amplifier AO₃.

In addition, one of the terminals of the second resistor R₂ is thus connected to the output of the fourth amplifier AO₄, while the other terminal is connected both to the second resistor R₂ and to the inverting input of the fourth amplifier AO₄. So, the terminals of the second resistor R₂ are connected respectively to each of the inverting inputs of the third and fourth operational amplifiers AO₃ and AO₄.

Furthermore, the outputs of the third and fourth operational amplifiers AO₃ and AO₄ are respectively connected to the inverting and non-inverting inputs of the fifth operational amplifier AO₅, wherein said fifth amplifier AO₅ makes a subtraction between the output signals from the third and fourth operational amplifiers AO₃ and AO₄.

The output of the fifth operational amplifier AO₅ is connected to the input of the filtration stage 23. Thus, at the output of the filtration stage 23, the measured voltage V_{R} is amplified and then filtered, and then returned to the input of the analogic-digital converter 13. For example, the amplification stage 19 makes it possible to amplify the input signal by a 1000 factor.

It shall be noted that said device 1 may comprise an alert means (not pictured), for example at the digital monitoring circuit 5 configured to warn the operator about the injection of a measurement current I_{R}, the end of the measurement and/or the determining (and display with the human-machine interface) of the electrical resistance value of a test element 2.

Said alert means is, for example, an audio, haptic and/or light signal. Said alert means can also be configured to warn that the measurement is completed and/or that it is right or not, in particular relatively to at least one preset electrical resistance value.

FIG. 4, is a block diagram that shows the treatment of the signal during the test of an element 2 by the device 1 of the invention.

Thus, the operator links the connection 9 on the test element 2 and launches the test to measure the resistance value of the element 2. The digital monitoring circuit 5 generates a digital setpoint Cₘ that equates to a measurement current value linked to the order of magnitude of the researched resistance value.

Then, the digital setpoint Cₘ is converted into a voltage V_{c} of the output setpoint current of the digital-analogic converter 11, said voltage V_{c} being, among other, a function of the reference voltage V_{ref}, of the number of bytes n₁ of the converter 11, of the values of the bytes aₙ, and of a coefficient k.

The coefficient k is a constant, and the output voltage is defined by the following formula:

$${V}_{out} = k \cdot {V}_{ref} \cdot {\sum }_{i = 1}^{n} ( {2}^{n - i} \cdot {a}_{n - i} )$$

with:
V_{ref}=maximum of the conversion
k=proportionality ratio
n=number of bytes of the converter
aₙ=value of the byte n (1 or 0)

The voltage V_{c} of setpoint current is then converted by the current generating assembly 17 into a measurement current I_{R}, said measurement current I_{R} being, among others, a function of the resistance value R_{SH}, and of the gain of the operational amplifier AO₂.

The measurement current I_{R} generated that way is injected into the test element 2 and generates a voltage V_{R} at the terminals of the test element 2. The voltage V_{R} is amplified and filtered by the amplification stage 19 to generate a voltage V′_{R}.

This voltage V′_{R} is the input voltage of the analogic-digital converter 13 and generates a digital signal L_{Uext} at the output of said converter, said digital signal L_{Uext} being a function of the reference voltage V_{ref}, of the number of bytes n₂ of the converter.

1. A device for measuring the resistance of an element, in particular of a structural element of an aircraft, said device comprising:
a digital monitoring circuit configured to, on one hand, monitor the value of the measurement current to inject into the test element and, on the other hand, calculate from the voltage value generated by the measurement current the value of the resistance of the test element;
a digital-analogic conversion stage configured to convert a digital signal into an analogic signal and vice versa;
an analogic measurement circuit connected to said digital monitoring circuit through said digital-analogic conversion stage and configured to:
generate a measurement current out of a digital setpoint from the digital monitoring circuit;
measure an analogic value of the voltage generated by the measurement current;
wherein the device comprises a reference voltage source connected to said conversion stage, wherein said conversion stage is configured to use the voltage value generated by said reference source for the conversion:
of digital signals, such as the digital setpoint that monitors the generation of a measurement current by said analogic measurement circuit, from the digital monitoring circuit into analogic signals for the analogic measurement circuit, and
of analogic signals, such as the voltage value at the terminals of the test element, from the digital measurement circuit into digital signals for the digital monitoring circuit.

2. The device according to claim 1, wherein the digital-analogic conversion stage comprises two distinct signal converters:
a first digital-analogic converter;
a second analogic-digital converter;
wherein said reference voltage source is connected to each of said converters.

3. The device according to claim 2, wherein the analogic measurement circuit comprises a current generating assembly configured to convert a voltage value out of the digital-analogic converter into a measurement current.

4. The device according to claim 1, wherein the current generating assembly comprises at least one reference resistance.

5. The device according to claim 1, wherein there is a measured voltage amplification stage generated by the measurement current.

6. The device according to claim 1, wherein the digital monitoring circuit is configured to send a current setpoint as a digital signal.

7. The device according to claim 2, wherein the voltage setpoint of the current out of the digital-analogic converter is a function of the reference voltage, of the number of bits n1 of the converter, of the values of the bits an, and of a coefficient k.

8. The device according to claim 3, wherein the voltage setpoint of the current is sent to the input of the current generating assembly to generate a measurement current.

9. The device according to claim 2, wherein the voltage at the input of the analogic-digital converter generates a digital signal at the output that is a function of the reference voltage, and of the number of bits n2 of the analogic-digital converter.

10. The device according to claim 1, wherein the digital monitoring circuit and the analogic measurement circuit are located on two distinct circuit boards.
